(19) United States
(12) Patent Application Publication
(10) Pub. No.: US 2026/0299678 A1
(43) Pub. Date: Oct. 1, 2026

(54) SYSTEM FOR VALIDATING A COMPONENT OF A MEANS OF TRANSPORTATION, METHOD, AND COMPUTER PROGRAM FOR OPERATING SUCH A SYSTEM

(71) Applicant: VOLKSWAGEN AKTIENGESELLSCHAFT, Wolfsburg (DE)

(72) Inventor: Cagdas Tekcan, Braunschweig (DE)

(21) Appl. No.: 19/475,731

(22) PCT Filed: Mar. 8, 2024
(86) PCT No.: PCT/EP2024/056183

§ 371 Date: Oct. 15, 2025

(30) Foreign Application Priority Data
Apr. 18, 2023 (DE) 10 2023 203 522.7

(51) Int. Cl. G06F 3/01; G01S 17/89; G09B 9/05

(52) U.S. Cl. CPC G06F 3/011; G01S 17/89; G09B 9/05

(57) ABSTRACT

A system for validating a component of a means of transportation includes a motion platform having at least three degrees of freedom for dynamic motion simulation of a cockpit of the means of transportation equipped with the component to be validated, a mixed reality display device configured to display an augmented environment to a user located in the cockpit, and a graphics system configured to calculate the augmented environment such that at least the user's hands and the component to be validated are perceptible by the user as real within a virtual environment. A method and computer program with instructions for operating the system are also disclosed.

### RELATED APPLICATIONS

The present application claims priority to International Patent Application No. PCT/EP2024/056183 to Cagdas Tekcan, filed Mar. 8, 2024, which claims priority from German Patent App. No. DE 10 2023 203 522.7, filed Apr. 18, 2023, the contents of each being incorporated by reference in their entirety herein.

### TECHNICAL FIELD

Aspects of the present disclosure are related to a system for validating a component of a means of transportation. Further aspects relate to a method and to a computer program including instructions for operating such a system.

### BACKGROUND

Driving simulators are commonly used for verifying or validating functions during the development of automobiles. Initially, projectors were predominantly used for visualization in driving simulators. In recent years, dynamic driving simulators incorporating virtual reality (VR) technologies have become prevalent. With virtual reality (VR), the user immersed in a completely virtual, computer-generated environment. Usually, head-mounted display (HMD) devices, for example VR glasses, are used for this purpose. The use of VR glasses has the advantage that no physical hardware components are required during the driving simulation. This allows changes in design, concept, or function to be implemented quickly and virtually.

However, VR glasses have the disadvantage that realistic, haptic interaction interactions are possible only to a very limited extent in virtual reality. One significant problem is that the test subject is isolated from the real world by the VR glasses. In particular, the test subject does not see his or her own hands, but only virtual representations of the hands. Due to the positioning inaccuracies of these virtual representations of the hands, functions, for example, in automobile development that require realistic, haptic interactions between the driver and the vehicle cannot be evaluated in virtual reality during early phases of the development process. These functions are therefore not evaluated until later development phases, where costs for modifications and optimizations increase substantially in these phases of the development process.

There have been attempts to use multiple hand tracking devices simultaneously to reduce the positioning inaccuracies of the virtual representations of the hands. However, the accuracy that has been achieved to date has not been sufficient. Solutions that are based on data gloves also have not provided the desired accuracy to date.

Augmented reality (AR) technologies can be used in combination with driving simulators as an alternative to VR technologies.

Augmented reality (AR) refers to the augmenting of the perception of the real world with virtual elements that are correctly registered in three-dimensional space and allow real-time interaction. Data glasses can be used, for example, for the representation of AR displays. Data glasses are worn like regular eyeglasses, but feature one or more projection units or displays that can be used to project information in front of the wearer's eyes or directly onto the retina. The glasses are designed such that the wearer can also perceive his or her surroundings.

Against this background, WO 2022/070 033 A1 describes a device for creating and managing prototypes comprising a plurality of physical supports and a digital medium comprising a CPU and a display and control device. The physical supports can be moved and adjusted by means of a plurality of respective actuators. The CPU is configured to actuate the actuators to adjust the positioning of the physical supports to predetermined positions, or to display the position of the physical supports.

AU 2018 200 822 A1 describes a simulator for a vehicle. The simulator utilizes green screening so that a user can see his or her hands or body in an augmented environment.

KR 2017 0 005 971 A describes a driving simulator. The driving simulator uses no or only a small number of physical components. A feel for the operation, a driving environment, and an environmental situation identical or similar to reality is provided in the form of augmented reality images.

In the described solutions, the particular test subject can see his or her hands, enabling improved haptic interaction between the test subject and real objects. However, further improved solutions for validating components that require interactions during driving are desirable.

### SUMMARY

Aspects of the present disclosure are directed to providing improved solutions for validating a component of a means of transportation in which interactions during driving are required.

Some aspects are described in the features recited in the independent claims, found below. Other aspects are described in the subject matter of the dependent claims.

Ini some examples, a system is disclosed for validating a component of a means of transportation comprises a motion platform, a mixed reality display device, and a graphics system. The motion platform is configured with at least three degrees of freedom for a dynamic motion simulation of a cockpit of the means of transportation in which the component to be validated is installed. The mixed reality display device is designed to display an augmented environment for a user located in the cockpit. The graphics system is designed to calculate the augmented environment. The augmented environment is calculated in such a way that at least the user's hands and the component to be validated are perceptible to the user in real terms within a virtual environment.

In some examples, a method is disclosed for operating a system for validating a component of a means of transportation, where the method comprises activating a motion platform of the system corresponding to a motion to be simulated; calculating an augmented environment to be displayed by a mixed reality display device of the system, the augmented environment being calculated in such a way that at least the user's hands and the component to be validated can be perceived by the user in real terms within a virtual environment; and transmitting graphics data of the augmented environment to the mixed reality display device.

In some examples, a computer program is disclosed that includes instructions which, during execution by a computer, prompt the computer to carry out the following steps for operating a system for validating a component of a means of transportation: activating a motion platform of the system corresponding to a motion to be simulated; calculating an augmented environment to be displayed by a mixed reality display device of the system, the augmented environment being calculated in such a way that at least the user's hands and the component to be validated can be perceived by the user in real terms within a virtual environment; and transmitting graphics data of the augmented environment to the mixed reality display device.

The term ‘computer’ as used herein shall be understood broadly. In particular, the term also encompasses workstations, distributed systems, and other processor-based data processing devices.

The computer program can, for example, be provided for electronic retrieval or be stored on a tangibly-embodied computer-readable memory medium.

Further features of the present disclosure can be derived from the following description and the accompanying claims, in conjunction with the figures.

### BRIEF DESCRIPTION OF THE DRAWINGS

To provide a better understanding of the principles of the present invention, embodiments of the invention will be described hereafter in greater detail based on the figures. It shall be understood that the invention is not limited to these embodiments, and that the described features can also be combined or modified, without departing from the scope of protection of the invention, as it is defined in the accompanying claims.

FIG. 1 schematically shows a system for validating a component of a means of transportation, according to some aspect of the present disclosure;

FIG. 2 schematically shows a method for operating the system from FIG. 1, according to some aspect of the present disclosure;

FIG. 3 schematically shows a system diagram of a solution according to the invention, according to some aspect of the present disclosure;

FIG. 4 schematically shows a painted cockpit, according to some aspect of the present disclosure;

FIG. 5 schematically shows the use of a depth sensor, according to some aspect of the present disclosure; and

FIG. 6 schematically shows the use of virtual masks, according to some aspect of the present disclosure.

### DETAILED DESCRIPTION

Embodiments of the present disclosure combine mixed reality technologies with a dynamic driving simulator. Mixed reality (MR) combines virtual reality elements and augmented reality elements, such that the real world is combined with virtual environments to create a new environment. The user interacts with the real environment and a virtual environment simultaneously. This enables integration of selected real components into the virtual simulation. As a result, the simulations can be configured such that the real components are used simultaneously with virtual components. One example includes a combination of a real steering wheel, a display, and the driver's body with an otherwise virtual interior. The mixed reality display device can, for example, be implemented as a head-mounted display. The component to be validated can be a physical component, a functionality, or software, such that, for example, contents shown on a display can be validated.

The combination of mixed reality and dynamic driving simulation provides options for the validation of functions. In a static design, the contents of the assessment are limited because many vehicle functions are checked while driving. The range of assessable contents, in particular during automobile development, is expanded by embodiments of the present disclosure because the driving simulator enables fulfillment of the driving task. The provided number of degrees of freedom for the dynamic motion simulation ensures that the user does not experience simulation sickness or that simulation sickness is decreased. Simulation sickness, also referred to in literature as motion sickness, occurs in the absence of a suitable motion simulation because the user is driving in the simulation while his or her body does not move in the real world. One advantage compared to dynamic driving simulators that utilize VR technologies is that the direct haptic interaction with operating elements enables a larger spectrum of assessable contents, for example during the development of automobiles.

In some embodiments, the motion platform is a hexapod. A hexapod provides six degrees of freedom and high dynamics. This enables a realistic driving simulation, whereby the occurrence of simulation sickness is avoided. At the same time, an overall experience is achieved for the user, and thus assessability of the component to be validated or the function thereof.

In some embodiments, the cockpit is painted, and the graphics system is configured to calculate the augmented environment using a chroma key technique. For the use of chroma key techniques, the cockpit can be partly or completely coated with a suitable color.

Alternatively, the components of the cockpit that are to be replaced by a virtual environment in the augmented environment can be produced directly in the selected color. Another option is to cover parts of the cockpit using correspondingly colored covers. The colors suited for chroma key techniques are green and blue hues, depending on the human skin color. The mixed reality display device shows the painted or covered parts of the cockpit implemented in the selected color in the form of virtual contents. The operating elements not implemented or painted or covered in this color, for example the steering wheel and touch displays, are, in contrast, shown in real terms.

In some embodiments, the mixed reality display device comprises a depth sensor, and the graphics system is configured to calculate the augmented environment using depth data of the depth sensor. For example, the depth sensor can be a LIDAR sensor. The depth sensor is preferably installed in the mixed reality display device. The use of depth data allows objects within a certain distance range that is selected by the user to be considered real, and thus not to be replaced by a virtual environment. It is advantageous that no extensive preparation of the cockpit is required.

In some embodiments, the graphics system is configured to calculate the augmented environment using a virtual mask. A virtual mask allows real and virtual contents to be separated with the aid of virtual boundaries, which can be determined in different two-dimensional or three-dimensional shapes. This solution also does not require extensive preparation of the cockpit.

In some embodiments, the system comprises a tracking system for tracking the cockpit. The tracking system can be an active or a passive tracking system or be configured to determine a pose of the cockpit from motion data of the motion platform. Such a tracking system is advantageous when virtual masks are used. To use virtual masks in the dynamic simulator, these should move along with the simulator.

Preparing the cockpit for the use of chroma key techniques requires a certain amount of effort. This is the case when different vehicles are being validated in the dynamic driving simulator because in this case each of the components of the cockpit must be moved into new positions. As a result, it may not be possible to attach a cover for the chroma key techniques due to the differing design. It may be advantageous in such cases to combine the above-described approaches. This way, it may be sufficient for the chroma key techniques to paint only a limited portion of the cockpit.

A system according to embodiments of the present disclosure may be used for validating a component of a motor vehicle, in particular of a passenger car or of a utility vehicle. As a result of embodiments of the present disclosure, vehicle functions, for example functions of autonomous driving, can be validated and developed at early development stages without physical prototypes.

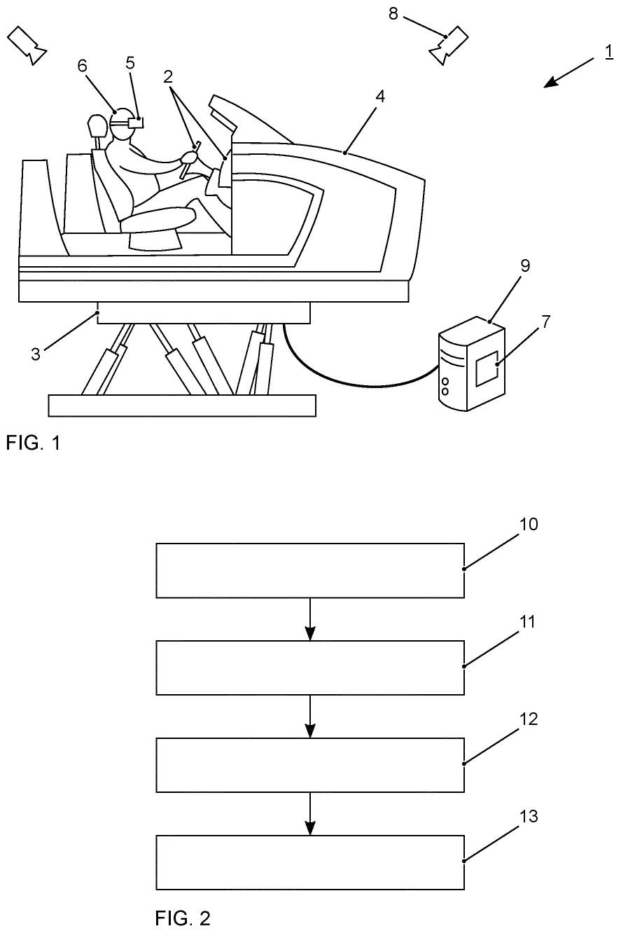

FIG. 1 schematically illustrates a system 1 for validating a component 2 of a means of transportation. The system 1 comprises a motion platform 3 having at least three degrees of freedom. In the illustrated example, the motion platform 3 is a hexapod having six degrees of freedom. Optionally, the hexapod can be mounted on a rotation platform, which is not shown here. The motion platform 3 enables a dynamic motion simulation of a cockpit 4, arranged on the motion platform 3, of the means of transportation in which the component 2 to be validated is installed. The cockpit 4 can be configured so as to be able to accommodate the respective ergonomics for different means of transportation. The means of transportation in the illustrated example is a motor vehicle, and the component 2 to be validated is a steering wheel of the motor vehicle. A user 6 wearing a mixed reality display device 5 is located in the cockpit 4. The mixed reality display device 5 displays an augmented environment to the user 6 and may, for example, be implemented as a head-mounted display. A graphics system 7, shown here as part of a control processor 9, is used to calculate the augmented environment. The graphics system 7 is configured to calculate the augmented environment such that at least the user's hands and the component 2 to be validated are perceptible by the user 6 in real terms within a virtual environment. For this purpose, the cockpit 4 may be painted. In this case, the graphics system 7 is configured to calculate the augmented environment using a chroma key technique. Alternatively or in addition, the mixed reality display device 5 may comprise a depth sensor, which is not shown here, for example a LIDAR sensor. In this case, the graphics system 7 is configured to calculate the augmented environment using depth data of the depth sensor. Additionally, the augmented environment may be calculated using virtual masks. In some embodiments, the cockpit 4 is tracked by a tracking system 8, such that the virtual masks move along with the cockpit 4 or the motion platform 3. The tracking system 8 may be implemented as an active or a passive tracking system 8. Alternatively, the pose of the cockpit 4 may be determined from the pose of the cockpit 4 from motion data of the motion platform 3.

FIG. 2 schematically illustrates a method for operating the system of FIG. 1. In the method, a motion platform of the system is moved 10 in a manner corresponding to a motion to be simulated. In addition, an augmented environment to be displayed by a mixed reality display device of the system is calculated 11. The augmented environment is calculated 11 such that at least a user's hands and a component to be validated are perceptible by the user in real terms within a virtual environment. For this purpose, the cockpit of the system may be painted. In this case, the augmented environment may be calculated 11 using a chroma key technique. Alternatively or in addition, the mixed reality display device may comprise a depth sensor, for example a LIDAR sensor. In this case, the augmented environment may be calculated 11 using depth data of the depth sensor. Additionally, the augmented environment may be calculated 11 using a virtual mask. In some embodiments, the cockpit is tracked by a tracking system, such that the virtual masks move along with the cockpit or the motion platform. The tracking data of the tracking system may be used to calculate the augmented environment. The various approaches may also be combined. The graphics data of the augmented environment resulting from the calculation are transmitted 12 to the mixed reality display device and displayed 13 by the mixed reality display device.

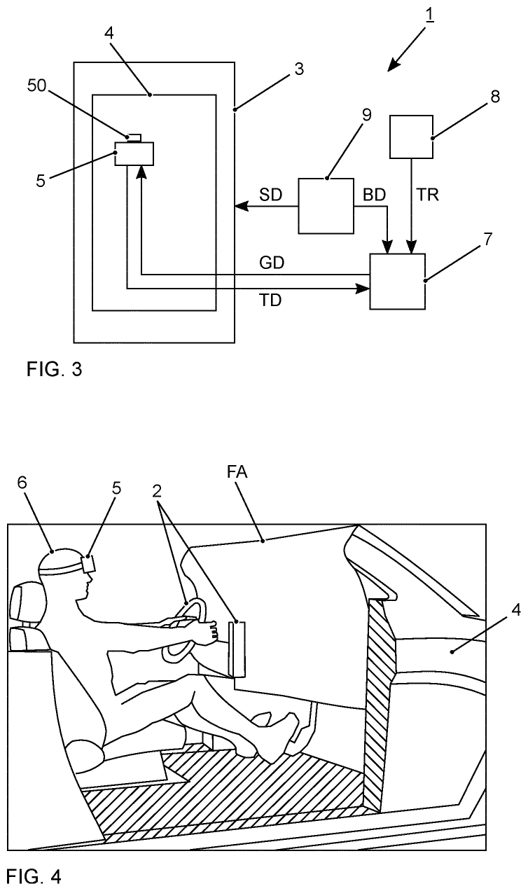

FIG. 3 schematically illustrates a system diagram of embodiments of the present disclosure. The system 1 comprises a motion platform 3 having a cockpit 4 arranged thereon, a mixed reality display device 5, and a graphics system 7. The graphics system 7 may be configured as an independent system or as part of a control processor 9 and generates graphics data GD for the mixed reality display device 5. The control processor 9 generates control data SD for the motion of the motion platform 3. The mixed reality display device 5 may comprise a depth sensor 50, which provides depth data TD for the graphics system 7. The system 1 may further comprise a tracking system 8 for tracking the cockpit 4, which provides tracking data TR. Alternatively or in addition, the control processor 9 may provide motion data BD of the motion platform 3 to the graphics system 7. The graphics system 7 uses the provided data BD, TD, TR during the calculation of an augmented environment, which is to be displayed by the mixed reality display device 5.

FIG. 4 schematically illustrates a painted cockpit 4. To be able to calculate the augmented environment using a chroma key technique, the cockpit, in the illustrated example, is partly coated with a suitable color, which is indicated by a hatched area in FIG. 4. Alternatively, the components of the cockpit 4 that are to be replaced by a virtual environment in the augmented environment may be produced directly in the selected color. Further, parts of the cockpit 4 in the illustrated example may be covered by a correspondingly colored cover FA. The colors suited for the chroma key techniques are green and blue hues, depending on the human skin color. The mixed reality display device 5 displays the painted parts or the covered parts of the cockpit 4 coated in the selected color in the form of virtual contents. Other components 2 not coated, painted or covered in this color, for example the steering wheel and touch displays, are, in contrast, displayed in real terms.

FIG. 5 schematically illustrates the use of a depth sensor 50 of the mixed reality display device 5. In this approach, a depth region TB is defined, which is visible to the user 6 in real terms. In addition, the cockpit 4 may be painted again in the illustrated example. Preparing the cockpit 4 for the use of chroma key techniques requires a certain amount of effort. As a result of using the defined depth region TB, it may suffice to paint only a limited part of the cockpit using the chroma key techniques. The required effort may be considerably reduced.

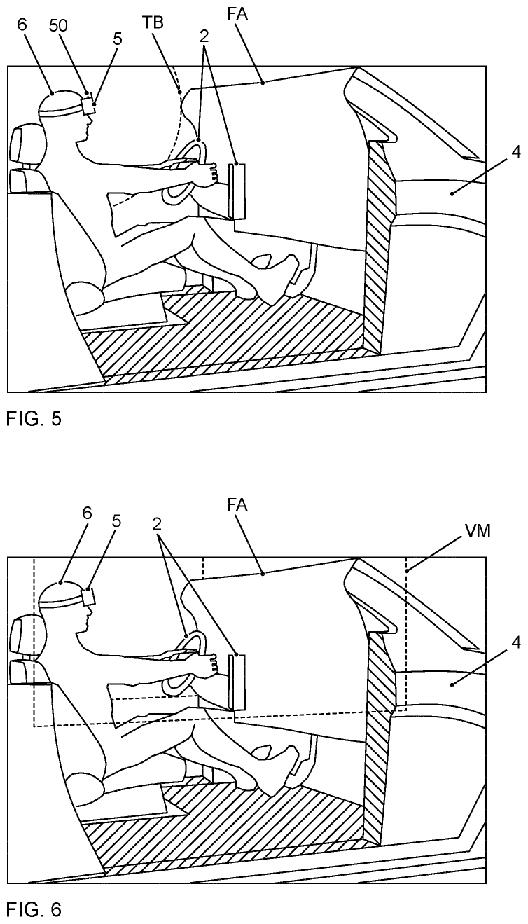

FIG. 6 schematically illustrates the use of virtual masks VM during the calculation of the augmented environment. Virtual masks VM may be defined for certain regions. These enable real and virtual contents to be separated using virtual boundaries. The boundaries may be determined in different two-dimensional or three-dimensional shapes. By using virtual masks VM, the effort for painting the cockpit 4 may be reduced. The painting may be limited to regions of the cockpit 4 that are not covered by a virtual mask VM.

### List of Reference Signs

1 system
2 component
3 motion platform
4 cockpit
5 mixed reality display device
50 depth sensor
6 user
7 graphics system
8 tracking system
9 control processor
10 activating a motion platform
11 calculating an augmented environment
12 transmitting graphics data
13 displaying the augmented environment
BD motion data
FA colored cover
GD graphics data
SD control data
TB depth region
TD depth data
TR tracking data
VM virtual mask

1-10. (canceled)

11. A system for validating a component of a means of transportation, the system comprising:
a motion platform comprising at least three degrees of freedom for dynamic motion simulation of a cockpit of the means of transportation, the cockpit being equipped with the component to be validated;
a mixed reality display device configured to display an augmented environment to a user located in the cockpit; and
a graphics system configured to calculate the augmented environment such that at least the user's hands and the component to be validated are perceptible by the user as real within a virtual environment.

12. The system of claim 11, wherein the motion platform comprises a hexapod.

13. The system of claim 11, wherein at least a portion of the cockpit is painted, and the graphics system is configured to calculate the augmented environment using a chroma key technique.

14. The system of claim 13, wherein the mixed reality display device comprises a depth sensor, and the graphics system is configured to calculate the augmented environment using depth data from the depth sensor.

15. The system of claim 14, wherein the depth sensor is a LIDAR sensor.

16. The system of claim 13, wherein the graphics system is configured to calculate the augmented environment using a virtual mask.

17. The system of claim 16, further comprising a tracking system configured to track the cockpit.

18. The system of claim 17, wherein the tracking system is an active tracking system or a passive tracking system.

19. The system of claim 17, wherein the tracking system is configured to determine a pose of the cockpit from motion data of the motion platform.

20. A method for validating a component of a means of transportation, the method comprising:
activating a motion platform having at least three degrees of freedom to simulate dynamic motion of a cockpit of the means of transportation, the cockpit being equipped with the component to be validated;
calculating an augmented environment to be displayed by a mixed reality display device to a user located in the cockpit, the augmented environment being calculated such that at least the user's hands and the component to be validated are perceptible by the user as real within a virtual environment; and
transmitting graphics data of the augmented environment to the mixed reality display device.

21. The method of claim 20, wherein the motion platform comprises a hexapod.

22. The method of claim 20, wherein at least a portion of the cockpit is painted, and calculating the augmented environment comprises using a chroma key technique.

23. The method of claim 22, wherein calculating the augmented environment comprises using depth data from a depth sensor of the mixed reality display device.

24. The method of claim 23, wherein the depth sensor is a LIDAR sensor.

25. The method of claim 22, wherein calculating the augmented environment comprises using a virtual mask.

26. The method of claim 25, further comprising tracking the cockpit using a tracking system.

27. The method of claim 26, wherein tracking the cockpit comprises using an active tracking system or a passive tracking system, or determining a pose of the cockpit from motion data of the motion platform.

28. A non-transitory computer-readable medium having instructions stored thereon that, when executed by one or more processors, cause the one or more processors to:
activate a motion platform having at least three degrees of freedom to simulate dynamic motion of a cockpit of a means of transportation, the cockpit being equipped with a component to be validated;
calculate an augmented environment to be displayed by a mixed reality display device to a user located in the cockpit, the augmented environment being calculated such that at least the user's hands and the component to be validated are perceptible by the user as real within a virtual environment; and
transmit graphics data of the augmented environment to the mixed reality display device.

29. The non-transitory computer-readable medium of claim 28, wherein the motion platform comprises a hexapod.

30. The non-transitory computer-readable medium of claim 28, wherein at least a portion of the cockpit is painted, and calculating the augmented environment comprises using a chroma key technique.
